(19) United States
(12) Patent Application Publication
(10) Pub. No.: US 2025/0062182 A1
(43) Pub. Date: Feb. 20, 2025

(54) THERMAL INTERCONNECT FOR INTEGRATED CIRCUITRY

(71) Applicant: Telefonaktiebolaget LM Ericsson (publ), Stockholm (SE)

(72) Inventors: Emil NYLANDER, Lund (SE); Per INGELHAG, Alingsås (SE); Benny GUSTAFSON, Spånga (SE); Agneta LJUNGBRO, Bjärred (SE)

(21) Appl. No.: 18/721,312

(22) PCT Filed: Dec. 22, 2021
(86) PCT No.: PCT/SE2021/051306

§ 371 Date: Jun. 18, 2024

(51) Int. Cl. H01L 23/367; H01L 23/00; H01L 23/373; H01L 23/498

(52) U.S. Cl. CPC H01L 23/3675; H01L 23/49833; H01L 24/16; H01L 24/81; H01L 23/3736; H01L 2224/16235; H01L 2224/81191; H01L 2224/81801

(57) ABSTRACT

There is disclosed an electronic device comprising a printed circuit board, PCB, the PCB having one or more thermal vias filled with thermally conductive material. The electronic device further having a package, the package including a substrate and a die, the die having an active side with integrated circuity, and a heat-removal side. The heat-removal side of the die is in thermally conductive connection with the one or more thermal vias via solder balls. The disclosure also pertains to related devices and methods.

### TECHNICAL FIELD

This disclosure pertains to electronics, in particular for high frequency communication.

### BACKGROUND

Modern electronics are becoming increasingly more powerful, but require increasingly tighter integration. Highly integrated electronics come with stronger requirements regarding tolerances and compactness (e.g., size or small areas), e.g. for connections.

### SUMMARY

It is an object of this disclosure to provide approaches allowing improved connections for electronic devices, in particular for connections allowing transfer of heat away from an active surface or side of integrated circuitry comprising a die.

There is disclosed an electronic device comprising a printed circuit board, PCB. The PCB comprises one or more thermal vias filled with thermally conductive material. The electronic device further comprises a package comprising a substrate and a die. The die has an active side with integrated circuity and a heat-removal side. The heat-removal side of the die is in thermally conductive connection with the one or more thermal vias via solder balls.

Moreover, a package for an electronic device is described. The package comprises a substrate and a die. The die has an active side with integrated circuity, and a heat-removal side. The heat-removal side is adapted for being connected or connectable, via a thermally conductive connection, to one or more thermal vias of a printed circuit board (PCB) via solder balls.

A method of soldering a package to a printed circuit board is considered. The printed circuit board comprises one or more thermal vias filled with thermally conductive material. The package comprises a substrate and a die, the die having an active side with integrated circuity and a heat-removal side. The method comprises soldering solder balls to provide a thermally conductive connection of the heat-removal side of the die with the one or more thermal vias.

Approaches described herein allow a compact arrangement of electronic components, with good heat removal properties. This is particularly useful for multi-element arrangements, e.g. antenna arrays with large numbers of antennas and/or sub-arrays of antennas. It may be considered that heat is transferable from the active side and/or material of the die via the solder balls, through the thermal vias.

A die may be considered comprising, and/or consisting of, and/or being implemented as and/or represented by, a block or mass of semiconducting material, e.g. based on and/or comprising and/or consisting of Si and/or Ge and/or Ga and/or As and/or S and/or a combination thereof, as applicable, in particular GaN or SiGe or GaAs, and/or which may comprise one or more doped zones and/or comprise integrated circuitry like functional electronic circuitry (e.g., representing one functionality and/or group of funtionalities, e.g. processing of signals, e.g. signals from and/or to one or more antennas, and/or controlling on or more antennas). The integrated circuitry and/or active side may produce heat while being operated, e.g. when connected to, and/or supplied with, electric power. Heat produced on the active side may be conducted away from the die on the heat-removal side. In general, the heat-removal side may be situated opposite of the active side. The active side and/or heat-removal side may be parallel to each other. It may be considered that the active side and/or heat removal side represent the largest outer surface of the die; in some cases, the active side and heat-removal side may have the same area size. In general, a die may have a plurality of surfaces, e.g., one of which may be associated to and/or represented by the active side, and/or one of which may be associated to and/or represented by the heat-removal side. The number of surfaces of a die may in some examples be 6 (or more, e.g. with sides cut to angled surfaces). A die may comprise, and/or be embedded and/or embeddable, in a substrate. A substrate may in general comprise and/or represent, for example, a laminate and/or mold (or mold compound), and/or glass, or similar material; different substrates or substrate layers may be of the same or different materials. The heat-removal side of the die may be free of the substrate, and/or the active side may be contacting and/or intended to contact the substrate. In some cases, a die may be a flip-chip die assembled onto the substrate. A package may comprise the die assembled to, and/or embedded in, the substrate, and/or comprising a mask on the heat-removal side of the die, the mask defining and/or providing and/or leaving uncovered connection points for solder balls.

It may be considered that the heat-removal side of the die comprises a metallic layer. The metallic layer may provide a heat conductive connection possibility. The metallic layer may be directly contactable and/or provide a heat conductive connection possibility, e.g. to provide a heat conductive connection to the die. It may be considered that solder balls are connected and/or connectable and/or soldered and/or solderable to the metallic layer. It may be considered that the metallic layer defines an outer surface of the die, in particular at the heat-removal side. The solder balls may in general be arranged or arrangeable at and/or contacting and/or on the heat-removal side of the die. In general, the heat removal side may be accessible and/or contactable for solder balls at least in part, or completely.

In general, a metallic material or metallic layer may comprise and/or consist of one or more metals, and/or metallic alloys. The metallic material and/or layer may comprise and/or consist of copper and/or aluminium and/or gold and/or silver (which may be considered heat conductive materials and/or metals). A connection in general may comprise and/or provide a possibility for physically connection, including contact, e.g. force-fit and/or friction-locked, and/or form-fit, and/or integrally-bonded (e.g., soldered and/or welded and/or fused and/or laminated). A heat conductive connection may be a connection, between connected layers and/or devices and/or components, allowing heat transfer via conduction, e.g. such that conduction is the dominant (by at least a factor of 10, or of 100) mode of heat transfer. In some cases, a heat conductive connection may be provided indirectly, e.g. between components and/or elements not in direct physical contact; in such cases, the heat conductive connection may be provided and/or facilitate by a series and/or layer of heat conductive connections between intermediate components and/or the components. A heat conductive connection may be electrically conductive, and/or provided by and/or between metallic material. A solder ball may be of a solder material, which may be a heat conductive material and/or a metallic material, e.g. a solder alloy, and/or may have lower melting point than a metallic layer or material it is to contact and/or soldered too. A solder ball may be implemented as, and/or represented by a solder bump and/or micro-bump and/or intended and/or subject to coining or flattening. In general, a solder ball and/or solder balls may be surrounded and/or embedded in an underfill material, which may be electrically non-conductive. The underfill material may be arranged to surround the solder balls after they have been soldered to the die and/or PCB.

A printed circuit board (PCB) may comprise one or a plurality of layers. A via may be considered a through hole through the one or more layers, e.g. provided by drilling through layers individually or in groups, or providing individual layers with holes (e.g., before combining and/or stacking them), or by drilling the via/through hole after combining and/or stacking the layers to form the basic PCB, or by being formed during the lamination process. A thermal via may be intended for providing heat conductive heat transfer; it may be filled or fillable with a heat conductive material, e.g. a heat conductive metallic material. A thermal via may include a wall coating, e.g. a metallic layer, which for example may prevent the heat conductive material from seeping into the PCB material, and/or may improve the contact and/or sticking power of the heat conductive material. A via may comprise, and/or be covered by a metallic layer (or multiple metallic layers, e.g. on opposite ends of the via), providing a connection area for a solder ball or to thermal interface material. In general, a PCB may comprise multiple layers, which may be of different materials; the layers may be connected and/or combined and/or stacked, e.g. based on lamination and/or soldering and/or glueing. At least one of the layers may be non-heat conductive and/or be a fire-retardant and/or represent a substrate layer. In general, a PCB may comprise one or more copper layers and/or substrate layers and/or fire-retardant layers and/or soldermask layers and/or screen layers. Layers may comprise copper and/or fiber-glass and/or epoxy and/or phenolics or other materials. A thermal via may go through at least one non-heat conductive layer, e.g. a substrate layer and/or fiberglass layer and/or fire-retardant layer. A thermal via may be considered in thermally conductive contact if material it is filled with is in thermally conductive contact. A thermal via may be connected and/or connectable, and/or intended for connection, to a heat sink, which may be attached or attachable to a PCB, e.g. a cooling body.

It may be considered that the solder balls may directly contact a metallic layer of the heat-removal side of the die and/or directly contact a semiconductor material of the die. This facilitates good heat removal from the die via heat conductive materials.

It may be considered that the electronic device may represent and/or comprise antenna circuitry. The antenna circuitry may be connected or connectable, and/or be adapted to control and/or operate, one or a plurality of antenna elements, e.g. 4 or more, or 8 or more, or 16 or more, antenna elements. Controlling and/or operating antenna elements may be collectively, e.g. as an antenna array and/or subarray, and/or may comprise transmitting and/or receiving signalling and/or providing power and/or processing signalling. Compact arrangement for dense antenna arrangements may be provided, e.g. with multiple antenna circuitries in a small area, e.g. for high frequency communication (e.g., 5 GHz or higher carrier frequency, or 10 GHz or higher, or 28 GHz or higher, or 60 GHz or higher, in particular 100 GHz or higher).

In some cases, the electronic device may represent and/or comprise a processor arrangement. The processor arrangement may comprise processing circuitry, e.g. one or more processors and/or controllers (e.g., microcontrollers and/or DSPs, Digital Signal Processors) and/or processor cores and/or ASICs (Application Specific Integrated Circuitry), and/or memories, e.g. RAM and/or EPROM and/or EEPROM. In particular, a memory may be arranged at and/or on and/or above the active side of the die; the die may comprise processing circuitry on the active side. Heat may be transported away via the solder balls, limiting heat load on the memory arrangement.

It may be considered that the electronic device may comprise, and/or may be connected or connectable, to a second package, in particular a memory, on a side corresponding to the active side of the die. The active side may comprise and/or provide processing circuitry, which may be connected or connectable to the memory and/or integrated circuitry of the second package (e.g., on a second die) for storing and/or retrieving information and/or data. The second package may represent and/or comprise memory and/or processing circuitry and/or antenna circuitry and/or power circuitry (e.g., on or more power amplifiers) and/or radio circuitry and/or communication circuitry.

There may be considered antenna circuitry comprising a device as described herein. Antenna circuitry may be adapted for controlling and/or operating, and/or may be connected or connectable, to one or more antenna elements, which may be controllable jointly by the antenna circuitry. Antenna circuitry may comprise one or more power amplifiers and/or one or more Analog-to-Digital Converters (ADCs), and/or DACs (Digital-to-Analog Converter), which may be connected or connectable to the same (e.g., multiple) antenna elements. The antenna circuitry may comprise the multiple antenna elements.

There is also described a wireless communication device comprising one or more devices as described herein, e.g. an electronic device and/or antenna circuitry. The wireless communication device may be a terminal and/or user equipment, or a base station or network node or access point or transmission and reception point (TRP), or similar. There may be considered a wireless communication device or terminal for wireless communication comprising a processor arrangement and/or an antenna circuitry as described herein.

### BRIEF DESCRIPTION OF THE DRAWINGS

The drawings are provided to illustrate concepts and approaches described herein, and are not intended to limit their scope. The drawings comprise:

FIG. 1, schematically showing an exemplary electronic device; and

FIG. 2, schematically showing another exemplary electronic device.

### DETAILED DESCRIPTION

Approaches described herein facilitate cooling of circuitry from the backside (heat-removal side) of silicon (or other semiconductor material of a die). There may be plating (e.g., metallic layer) on the heat removal side (e.g., backside of Si). Solder balls may be connected to the die material, e.g. Silicon, on the heat removal side. Solder balls may be connected to thermal vias (e.g., stacked vias) through a PCB, for example ending up in a plated area on the PCB and connected thermally to a heat sink. e.g. with a Thermal Interface Material. By using this technology, tight tolerances may be kept (which may be needed, e.g., when building larger antenna arrays with AiP for mmW products), and enable both thermal and electrical interconnects in a small area. The distance between a thermal via and an electrical connection in the PCB can be kept at the smallest distance allowed by PCB technology, an advantage compared to coined solutions. In a Package on

Package solution (e.g., processor and memory arranged together, in particular for memory connected on top of application processor) heat dissipation may be a problem since the memory may be sensitive to heat. Approaches facilitate removing the heat from the processor from the backside of the die.

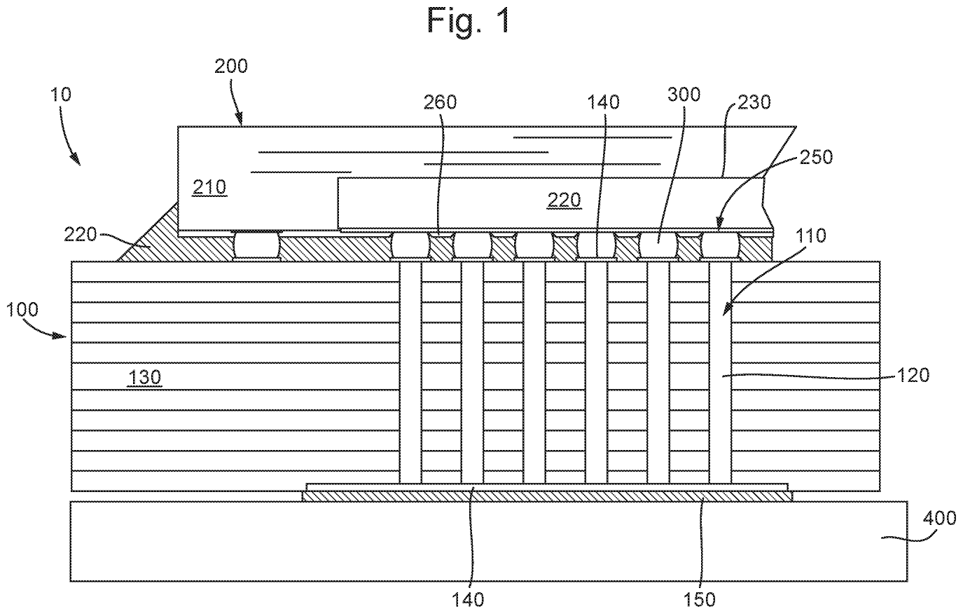

FIG. 1 schematically shows an electronic device 10, which comprises a PCB 100. The PCB may comprise thermal vias 110 filled with thermally conductive material 120. The vias 110 may be stacked vias, going through layers 130 of the PCB. The electronic device may also comprise a package 200, with a substrate 210 and a die 220. The die 220 may comprise an active side 230 with integrated circuitry like processing circuitry and/or antenna circuitry. The die 220 also may have a heat-removal side 250 opposite of the active side. The heat-removal side 250 may be covered by a metallic layer. A mask 260 may be provided, which may be non-heat conductive and/or not electrically conductive. Underfill 270 material may be used, e.g. to enhance the solder joint reliability. The mask may cover the heat-removal side 250 and/or metallic layer, but leave open contact points for solder balls 300 to contact the metal layer and/or semiconductor material of the die 220. The solder balls 300 contact metallic layers 140 of the vias 110; the vias lead to a common metallic layer 140 on the opposite of the PCB (directed away from the package 200), to contact thermal interface material 150, which may connect to a heat sink 400. When the circuitry on the active side 230 is operated, it will produce heat. The approaches allow removing the heat via the backside (heat-removal side), utilising the solder balls in close connection to the semiconductor material of the die 220.

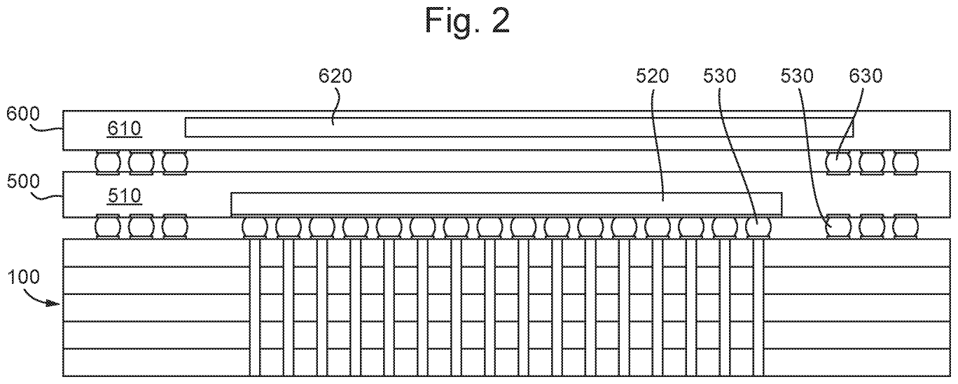

FIG. 2 schematically shows another exemplary electronic device, comprising a processor arrangement (with a processing circuitry). The PCB 100 and heat sink arrangement may be similar to the one shown in FIG. 1. The package 500 may represent a package as shown in FIG. 1, in this case with a substrate 510 and a die 520, wherein the circuitry on the active side may represent processing circuitry, e.g. a processor or controller or ASIC, or other heat-producing circuitry, e.g. radio circuitry and/or power circuitry. A heat conductive connection between the PCB 100 and the die 520 (in the example, also to the substrate 510) is provided by solder balls 530. A second package 600, e.g., representing a memory, is arranged on top the first package 500. The second package 600 may comprise a substrate 610 and die 620, and be connected with solder balls 630 on the substrate 610 to the substrate 510 of the first package 500. The die 620 may be completely embedded, and/or be embedded from a top side and a bottom side, in the substrate 610, and/or not be directly connected or connectable to solder balls and/or the first package. As heat produced by the processing circuitry of die 520 can be removed efficiently via the solder balls 530 connecting directly to the heat-removal side of the die 520, the impact of heat on the second package is limited. The arrangement of FIG. 2 is particularly suitable for small and/or mobile device, e.g. wireless device for wireless communication like terminals or user equipment, and/or IoT devices (Internet-of-Things).

Wireless communication may pertain to radio communication using a carrier frequency range of 100 MHz or more, or 1 GHz or more, or 10 GHz or more, or 50 GHz or more, or 75 GHz more, or 100 GHz or more. Bandwidth for communication may be at least 5% of the carrier frequency, or at least 8% of the carrier frequency. Frequencies of 10 GHz or more, or 30 GHz or more, may be considered mmW (mm Wavelengths).

Circuitry may comprise integrated circuitry. Processing circuitry may comprise one or more processors and/or controllers (e.g., microcontrollers), and/or ASICs (Application Specific Integrated Circuitry) and/or FPGAs (Field Programmable Gate Array), or similar. It may be considered that processing circuitry comprises, and/or is (operatively) connected or connectable to one or more memories or memory arrangements. A memory arrangement may comprise one or more memories. A memory may be adapted to store digital information. Examples for memories comprise volatile and non-volatile memory, and/or Random Access Memory (RAM), and/or Read-Only-Memory (ROM), and/or magnetic and/or optical memory, and/or flash memory, and/or hard disk memory, and/or EPROM or EEPROM (Erasable Programmable ROM or Electrically Erasable Programmable ROM).

A wireless communication device (also referred to as wireless device) may in general comprise, and/or be adapted to utilise, processing circuitry and/or radio circuitry, in particular a transmitter and/or transceiver and/o receiver, to process (e.g., trigger and/or schedule) and/or transmit and/or receive signalling like data signalling and/or control signalling and/or reference signalling, and/or to perform beam switching. A wireless device may be implemented as terminal or UE; in some cases, it may however be implemented as network node, in particular a base station or relay node or IAB node, in particular to provide MT (Mobile Termination) functionality for such. In general, a wireless device may comprise and/or be adapted for transmission or reception diversity, and/or may be connected or connectable to, and/or comprise, antenna circuitry, and/or two or more independently operable or controllable antenna arrays or arrangements, and/or transmitter circuitries and/or antenna circuitries, and/or may be adapted to use (e.g., simultaneously) a plurality of antenna ports, e.g. controlling transmission or reception using the antenna array/s, and/or to utilise and/or operate and/or control two or more transmission sources, to which it may be connected or connectable, or which it may comprise. The wireless device may comprise multiple components and/or transmitters and/or transmission sources and/or TRPs (and/or be connected or connectable thereto) and/or be adapted to control transmission and/or reception from such.

In this disclosure, for purposes of explanation and not limitation, specific details are set forth (such as particular network functions, processes and signaling steps) in order to provide a thorough understanding of the technique presented herein. It will be apparent to one skilled in the art that the present concepts and aspects may be practiced in other variants and variants that depart from these specific details.

For example, the concepts and variants are partially described in the context of Long Term Evolution (LTE) or LTE-Advanced (LTE-A) or New Radio mobile or wireless communications technologies, or in the context of 6G technology; however, this does not rule out the use of the present concepts and aspects in connection with additional or alternative mobile communication technologies such as the Global System for Mobile Communications (GSM) or IEEE standards as IEEE 802.11ad or IEEE 802.11 ay. While described variants may pertain to certain Technical Specifications (TSs) of the Third Generation Partnership Project (3GPP), it will be appreciated that the present approaches, concepts and aspects could also be realized in connection with different Performance Management (PM) specifications.

Moreover, those skilled in the art will appreciate that the services, functions and steps explained herein may be implemented using software functioning in conjunction with a programmed microprocessor, or using an Application Specific Integrated Circuit (ASIC), a Digital Signal Processor (DSP), a Field Programmable Gate Array (FPGA) or general purpose computer. It will also be appreciated that while the variants described herein are elucidated in the context of methods and devices, the concepts and aspects presented herein may also be embodied in a program product as well as in a system comprising control circuitry, e.g. a computer processor and a memory coupled to the processor, wherein the memory is encoded with one or more programs or program products that execute the services, functions and steps disclosed herein.

It is believed that the advantages of the aspects and variants presented herein will be fully understood from the foregoing description, and it will be apparent that various changes may be made in the form, constructions and arrangement of the exemplary aspects thereof without departing from the scope of the concepts and aspects described herein or without sacrificing all of its advantageous effects. The aspects presented herein can be varied in many ways.

1. An electronic device comprising:
a printed circuit board, PCB, the PCB comprising one or more thermal vias filled with thermally conductive material; and
a package, the package comprising a substrate and a die, the die having an active side with integrated circuity, and a heat-removal side, the heat-removal side of the die is being in thermally conductive connection with the one or more thermal vias via solder balls.

2. A package for an electronic device, the package comprising:
a substrate; and
a die, the die having an active side with integrated circuity, and a heat-removal side, the heat-removal side being adapted for being connectable via a thermally conductive connection to one or more thermal vias of a printed circuitry board, PCB, via solder balls.

3. A method of soldering a package to a printed circuit board, PCB, the PCB comprising one or more thermal vias filled with thermally conductive material, the package comprising a substrate and a die having an active side with integrated circuity and a heat-removal side, the method comprising:
soldering solder balls to provide a thermally conductive connection of the heat-removal side of the die with the one or more thermal vias.

4. The device according to claim 1, wherein the heat-removal side of the die comprises a metallic layer.

5. The device according to claim 1, wherein the solder balls one or both directly contact a metallic layer of the heat-removal side of the die and/or and directly contact a semiconductor material of the die.

6. The device according to claim 1, wherein the electronic device one or both represents and/or and comprises antenna circuitry.

7. The device according to claim 1, wherein the electronic device one or both represents and comprises a processor arrangement.

8. The device according to claim 1, wherein the electronic device one or both comprises, and is connected or connectable to a second package on a side corresponding to the active side of the die, wherein the second package is a memory.

9. The device according to claim 1, wherein the device is comprised in an antenna circuitry.

10. The device according to claim 1, wherein the device is comprised in a wireless device.

11. The package according to claim 2, wherein the heat-removal side of the die comprises a metallic layer.

12. The package according to claim 2, wherein the solder balls one or both directly contact a metallic layer of the heat-removal side of the die and directly contact a semiconductor material of the die.

13. The package according to claim 2, wherein the electronic device one or both represents and comprises antenna circuitry.

14. The package according to claim 2, wherein the electronic device one or both represents and comprises a processor arrangement.

15. The package according to claim 2, wherein the electronic device one or both comprises, and is connected or connectable to a second package on a side corresponding to the active side of the die, wherein the second package is a memory.

16. The package according to claim 2, wherein the device is comprised in an antenna circuitry.

17. The package according to claim 2, wherein the device is comprised in a wireless device.

18. The device according to claim 4, wherein the solder balls one or both directly contact a metallic layer of the heat-removal side of the die and directly contact a semiconductor material of the die.

19. The device according to claim 4, wherein the electronic device one or both represents and comprises antenna circuitry.

20. The device according to claim 4, wherein the electronic device one or both represents and comprises a processor arrangement.
